(19) United States
(12) Patent Application Publication
(10) Pub. No.: US 2002/0137268 A1
(43) Pub. Date: Sep. 26, 2002

(54) Method of forming silicide contacts and device incorporation same

(76) Inventors: John G. Pellerin, Austin, TX (US); Jon D. Cheek, Round Rock, TX (US); Robert Dawson, Austin, TX (US); Frederick N. Hause, Austin, TX (US); Scott D. Luning, Austin, TX (US)

Correspondence Address: J. Mike Amerson, Williams, Morgan & Amerson, P.C., Suite 250, 7676 Hillmont, Houston, TX, 77040, US

(21) Appl. No.: 09/812,373

(22) Filed: Mar. 20, 2001

(51) Int. Cl. H01L 21/336; H01L 21/8234

(52) U.S. Cl. 438/197; 438/299

(57) ABSTRACT

A transistor, comprising a semiconducting substrate, a gate insulation layer positioned above the substrate, a gate electrode positioned above the gate insulation layer, a plurality of source/drain regions formed in the substrate, a first and a second sidewall spacer positioned adjacent the gate electrode, and a metal silicide layer formed above each of the source/drain regions, a portion of the metal silicide layer being positioned adjacent the first sidewall spacer and under the second sidewall spacer. The method comprises forming a transistor by forming a gate insulation layer and a gate electrode above a semiconducting substrate, forming a first sidewall spacer adjacent the gate electrode, forming a metal silicide layer adjacent the first sidewall spacer and above previously formed implant regions in the substrate, forming a second sidewall spacer above a portion of the metal silicide layer and adjacent the first sidewall spacer, and forming additional metal silicide material above the metal silicide layer extending beyond the second sidewall spacer.

### BACKGROUND OF THE INVENTION

1. Field of the Invention

The present invention is generally directed to the field of semiconductor processing, and, more particularly, to a method of forming metal silicide contacts on a transistor device, and a device incorporating same.

2. Description of the Related Art

There is a constant drive within the semiconductor industry to increase the operating speed of integrated circuit devices, e.g., microprocessors, memory devices, etc. This drive is fueled by consumer demands for computers and electronic devices that operate at increasingly greater speeds. This demand for increased speed has resulted in a continual reduction in the size of semiconductor devices, e.g., transistors. That is, the size of many components of a typical field effect transistor, e.g., channel length, source/drain junction depths, gate dielectric thickness, etc., are reduced. For example, all other things being equal, the smaller the channel length of the transistor, the faster the transistor will operate. Thus, there is a constant drive to reduce the size, or scale, of the components of a typical transistor to increase the overall speed of the transistor, as well as integrated circuit devices incorporating such transistors. However, the reduction in the channel length also requires a reduction in the depth of the source and drain regions adjacent the gate conductor.

One operation that is typically performed on traditional semiconductor devices is known as salicidation. In general, salicidation involves the process of forming a layer of refractory metal, e.g., cobalt, titanium, nickel, platinum or tungsten, above a gate conductor and/or the source/drain regions of a transistor device, and, thereafter, subjecting the device to a heat treatment process such that a metal silicide, e.g., cobalt silicide, titanium silicide, nickel silicide, platinum silicide or tungsten silicide, is formed where the refractory metal is exposed to silicon. The purpose of the salicidation process is to, among other things, reduce the resistance of the components subject to the salicidation process, thereby increasing the operating speed of the device.

One illustrative process flow for forming an illustrative NMOS transistor 10 having such metal silicide contacts will now be described with reference to FIGS. 1A-1C. As shown in FIG. 1A, a semiconducting substrate 11 has shallow trench isolation regions 14 formed therein to thereby define an active area 15 of the substrate 11. A gate insulation layer 16, e.g., silicon dioxide, and a gate electrode layer 18, e.g., polysilicon, are formed above a surface 12 of the substrate 11 by forming the appropriate layers of material and then performing one or more etching processes to pattern the layers. Thereafter, extension implant regions 20 are formed in the substrate 11 by performing an ion implantation process. Note that during this process, the extension implant regions 20 are generally self-aligned with respect to sidewalls 18A of the gate electrode 18. For PMOS devices, a relatively small sidewall spacer (not shown) may be formed adjacent the gate electrode 18 prior to the extension implant process to compensate for increased mobility of some dopant atoms that may be implanted in PMOS devices, e.g., boron.

Thereafter, as indicated in FIG. 1B, a sidewall spacer 22 is formed adjacent the gate electrode 18. The sidewall spacer 22 may be formed by depositing an appropriate layer(s) of spacer material followed by performing an anisotropic etching process. The width of the spacer 22 at the point where the spacer 22 intersects the surface 12 of the substrate 10 may range from range from approximately 200-1500 Å. After the formation of the spacer 22, a source/drain implant process is performed to form source/drain implant regions 24. Note that during this process, the source/drain implant regions 24 are generally self-aligned with respect to the sidewall spacer 22. In general, the source/drain implant regions 24 are deeper and have a higher concentration of dopant atoms as compared to the extension implant regions 20. Due to the relatively high concentration of dopant atoms used during the source/drain implant process, only the portion of the extension implant region 20 protected by the sidewall spacer 22 continues to have a relatively light concentration of dopant atoms. This area is generally referred to as source/drain extensions 20A of the transistor 10. Note that, in FIG. 1B, the various implant regions are depicted in their implanted positions. After one or more anneal processes are performed on the device, the implanted dopant atoms will move or migrate from the implanted positions to the approximate positions indicated in FIG. 1C.

Next, metal silicide layers or contacts 28 are formed above the source/drain regions and the gate electrode 18. The metal silicide layers 28 typically have a thickness on the order of approximately 80-300 Å. The metal silicide layers 28 may be formed by depositing a layer (not shown) comprised of approximately 40-150 Å of an appropriate refractory material, e.g., cobalt, titanium, nickel, platinum, tungsten, etc., and thereafter performing one or more anneal processes to convert the portions of the refractory metal layer in contact with a silicon surface into a metal silicide, e.g., cobalt silicide, titanium silicide, etc. The portions of the refractory metal layer that are in contact with non-silicon surfaces, e.g., sidewall spacer 22, are not converted to a metal silicide, and they may be subsequently removed by chemical etch (wet) processes.

Traditional metal silicide contacts, such as the contacts 28 described above, are formed only above the portions of the completed source/drain regions of the device that lay beyond the sidewall spacer 22, i.e., they are only formed in the area between the sidewall spacer 22 and the isolation regions 14. Stated another way, traditional metal silicide contacts are not formed over the extension implant regions 20A under the sidewall spacer 22. One reason for this is that, during the process of converting the refractory metal to a metal silicide, some of the underlying implant regions are consumed. Thus, forming thick metal silicide contacts, e.g., on the order of 80-300 Å, above the shallow extension implant regions 20A would likely consume all or much of the extension implant 20A, thereby destroying or degrading device performance. This problem has become even more pronounced as device geometries continue to shrink because the depths of the source/drain extensions 20A (as well as the other implanted regions) are also reduced accordingly.

Another problem associated with traditional silicide contacts is that they are not placed as close to the gate electrode 18 as would otherwise be desired. In general, it would be desirable to have the metal silicide contacts 28 that are formed above the source/drain regions positioned as close as possible to the channel region of the device to reduce the resistance of the electrical path of the device from source to drain while not establishing a short circuit path with the gate electrode 18. However, as stated above, the location of the relatively shallow extension implant regions 20A prevents the formation of relatively thick metal silicide contacts above the extension implant regions 20A, thereby forcing the metal silicide contacts to be positioned further away from the gate electrode.

The present invention is directed to solving, or reducing, some or all of the aforementioned problems.

### SUMMARY OF THE INVENTION

A novel transistor device and method of making same is disclosed herein. In one illustrative embodiment, the transistor comprises a semiconducting substrate, a gate insulation layer positioned above the substrate, a gate electrode positioned above the gate insulation layer, and a plurality of source/drain regions formed in the substrate. The transistor further comprises a first and a second sidewall spacer positioned adjacent the gate electrode, and a metal silicide layer formed above each of the source/drain regions, a portion of the metal silicide layer being positioned adjacent the first sidewall spacer and under the second sidewall spacer.

A method of forming a transistor is also disclosed herein. In one illustrative embodiment, the method comprises forming a gate insulation layer and a gate electrode above a semiconducting substrate, forming a first sidewall spacer adjacent the gate electrode, and forming a metal silicide layer adjacent the first sidewall spacer and above previously formed implant regions in the substrate. The method further comprises forming a second sidewall spacer above a portion of the metal silicide layer, and forming additional metal silicide material above the metal silicide layer extending beyond the second sidewall spacer.

### BRIEF DESCRIPTION OF THE DRAWINGS

The invention may be understood by reference to the following description taken in conjunction with the accompanying drawings, in which like reference numerals identify like elements, and in which: FIGS. 1A-1C depict one illustrative prior art process flow for forming metal silicide contacts on a semiconductor device; and

FIGS. 2A-2D depict one illustrative embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

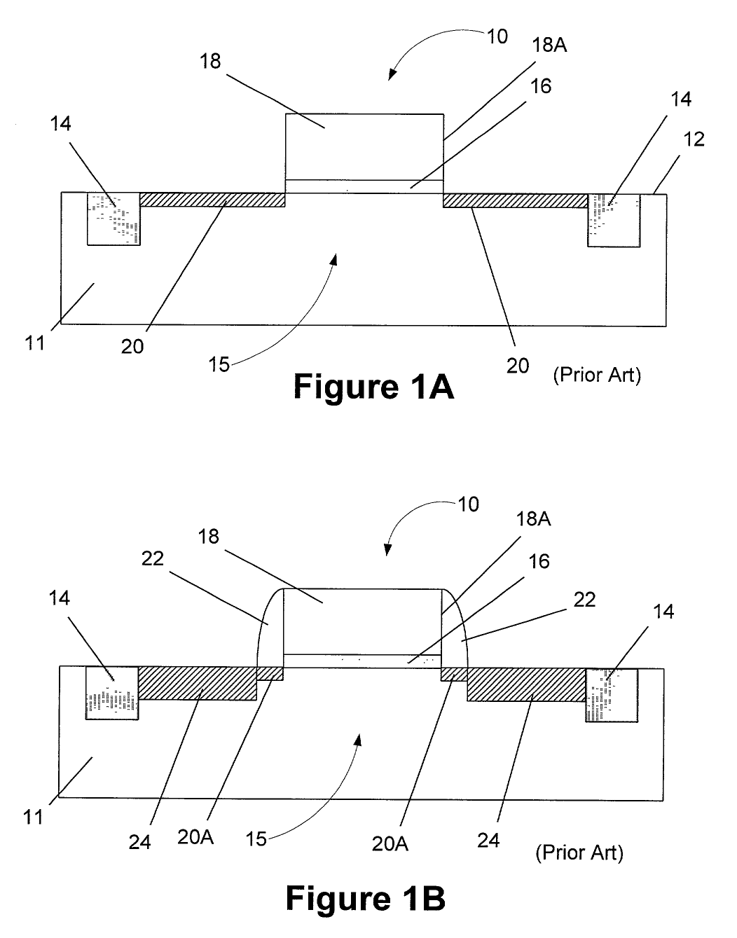

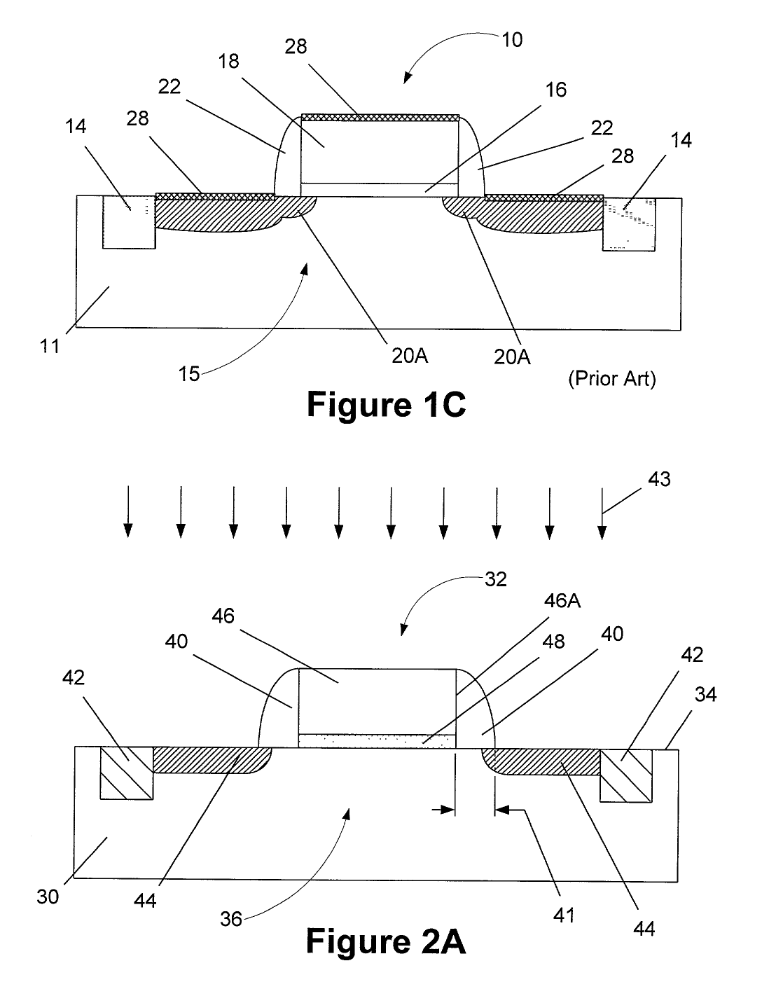

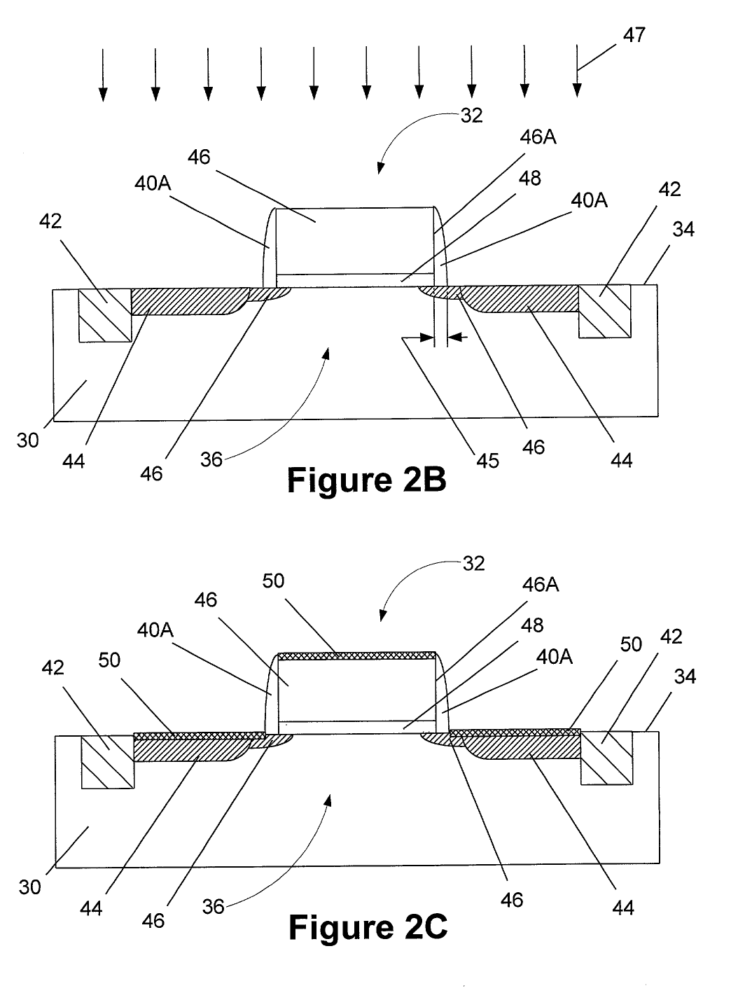

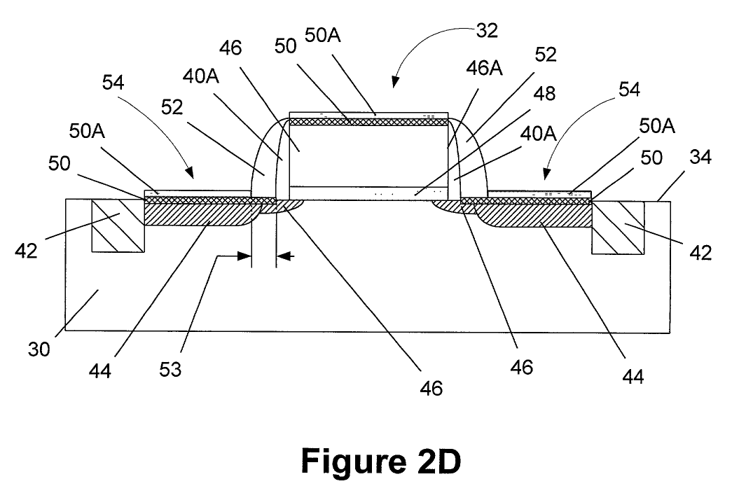

The present invention will now be described with reference to FIGS. 2A-2B. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features depicted in the drawings may be exaggerated or reduced as compared to the size of those feature sizes on fabricated devices. Nevertheless, the attached drawings are included to describe and explain illustrative examples of the present invention.

In general, the present invention is directed to forming metal silicide contacts on a semiconductor device, and a device incorporating such contacts. As will be readily apparent to those skilled in the art upon a complete reading of the present application, the present method is applicable to a variety of technologies, e.g., NMOS, PMOS, CMOS, etc., and is readily applicable to a variety of devices, including, but not limited to, logic devices, memory devices, etc.

As shown in FIG. 2A, a partially formed transistor 32 is formed above a surface 34 of a semiconducting substrate 30. In one illustrative embodiment, the semiconducting substrate 30 is comprised of silicon. Shallow trench isolation regions 42 are formed in the substrate 30 to thereby define an active area 36 where the transistor 32 will be formed. At the stage of manufacture depicted in FIG. 2A, the transistor 32 is comprised of a gate insulation layer 48, a gate electrode 46, a sidewall spacer 40, and source/drain implant regions 44.

The gate insulation layer 48 may be comprised of a variety of materials, e.g., a metal oxide, metal silicate, silicon dioxide, silicon nitride, an oxynitride, a silicon nitride/silicon dioxide bilayer, etc., and it may be formed by a variety of techniques, e.g., chemical vapor deposition (CVD), low pressure chemical vapor deposition (LPCVD), thermal growth, etc. In one illustrative embodiment, the gate insulation layer 48 is comprised of a thermally grown layer of silicon dioxide having a thickness ranging from approximately 20-50 Å. Similarly, the gate electrode 46 may be comprised of a variety of materials, e.g., polysilicon, a metal, etc. As will be recognized by those skilled in the art, the gate insulation layer 48 and the gate electrode 46 depicted in FIG. 2A may be formed by forming the appropriate layers of material and thereafter, using traditional photolithography and etching techniques, patterning the layers to result in the structures depicted in FIG. 2A.

The sidewall spacer 40 may be formed by forming an appropriate layer (not shown) of material above the surface of the substrate 30 and thereafter performing an anisotropic etching process to define the sidewall spacer 40 positioned adjacent the sidewall 46A of the gate electrode 46. The sidewall spacer 40 may be comprised of a variety of materials, e.g., silicon dioxide, silicon oxynitride, silicon nitride, an oxide, an oxynitride, etc. Moreover, the layer from which the sidewall spacer 40 may be formed can be manufactured using a variety of techniques, e.g., CVD, LPCVD, etc. In one illustrative embodiment, a thickness 41 of the sidewall spacer 40 may range from approximately 200-1500 Å.

Alternatively, although not shown in the drawings, the sidewall spacer 40 may have a dual-layer construction, and it may be formed as follows. A first layer of material, e.g., silicon dioxide, having a thickness of approximately 50-250 Å may be conformally deposited above the gate electrode 46 and the surface 34 of the substrate 30 and anisotropically etched to form a residual spacer only on the sidewall of the gate electrode 46. Thereafter, a second layer comprised of silicon nitride (or some other material that may be selectively etched with respect to the first layer) having a thickness ranging from approximately 400-1400 Å may be conformally deposited above the first layer. Thereafter, one or more anisotropic etching processes may be performed on the first and second layers to define a dual-layer sidewall spacer (not shown) comprised of, e.g., silicon dioxide and silicon nitride.

Thereafter, as indicated in FIG. 2A, an ion implantation process, as indicated by arrows 43, is performed to form source/drain implant regions 44 in the substrate 30. For an illustrative NMOS device, this implant process 43 may be comprised of approximately 1-10×10¹⁵ ions/cm² of arsenic or phosphorous at an implant energy of approximately 10-80 keV. As initially implanted, the source/drain implant regions 44 will generally be self-aligned with respect to the sidewall spacer 40, although that is not depicted in FIG. 2A. At some point during the process of manufacturing the device, one or more anneal processes will be performed to repair the damage to the lattice structure of the semiconducting substrate 30 due to the implantation process 43, and to activate the dopant atoms implanted during the ion implantation process 43. During this anneal process, the dopant atoms in the source/drain implant regions 44 will migrate, or move, in a more or less isotropic fashion such that a portion of the implant region 44 will extend under the sidewall spacer 40, as indicated in FIG. 2A. If desired, an anneal process may be performed on the source/drain implant regions 44 immediately after the implantation process 43 is performed. Such an anneal process may be performed at a temperature ranging from approximately 900-1100° C. for a duration of approximately 3-20 seconds in a rapid thermal anneal (RTA) chamber. The spacers 40 can then be removed by wet or dry chemical etch processes which are selective (do not attack) the substrate, implanted regions, or gate insulation or gate electrode.

Thereafter, as shown in FIG. 2B, a relatively thin sidewall spacer 40A is formed adjacent the gate electrode 46. The spacer 40A may have a thickness 45 ranging from approximately 50-250 Å, and it may be formed by a variety of techniques. In one embodiment, the spacer 40A is formed by reducing the thickness of the original sidewall spacer 40. In the case where the original spacer 40 is comprised of a single material, e.g., silicon dioxide, the width of the original spacer 40 may be reduced by subjecting the original spacer 40 to an additional anisotropic etching process for a desired period of time. Alternatively, in the case where the original spacer 40 is a dual-layer spacer, like the one described previously, an initial wet etching process may be performed to remove the silicon nitride, producing an approximately “L”-shaped silicon dioxide structure adjacent the gate electrode 46. Thereafter, an anisotropic etching process may be performed to define the sidewall spacer 40A from this L-shaped structure. Yet another alternative would be to remove the original spacer 40 entirely, and, thereafter, conformally deposit a relatively thin layer of the desired material, e.g., silicon dioxide, over the gate electrode 46 and then perform an anisotropic etching process to define the thin sidewall spacer 40A. Of course, the size of the spacer 40A will vary from device to device, and the particular reduction parameters described above should not be considered a limitation of the present invention unless they are specifically recited in the appended claims.

Thereafter, as indicated by arrows 47, a second ion implantation process is performed to form extension implant regions 46 in the substrate 30. For an illustrative NMOS device, the implant process 47 may involve implanting arsenic at a concentration ranging from 1-4×10¹⁵ ions/cm² at an energy level ranging from 0.5-7 keV. As implanted, the extension implant regions 46 will be generally self-aligned with respect to the sidewall spacer 40A, although that is not indicated in FIG. 2B. At some point during the process, one or more anneal processes will be performed on the device to repair the damage to the lattice structure of the substrate and to activate the dopant atoms implanted during the process 47. This will result in the migration, or movement, of some of the implanted dopant atoms under the sidewall spacer 40A and, to some extent, under the gate electrode 46. If the anneal process is performed at this time, it may be performed at a temperature ranging from approximately 950-1000° C. and for a duration of approximately 0 (spike RTA) to 10 seconds in an RTA chamber.

Thereafter, as shown in FIG. 2C, relatively thin metal suicide layers or contacts 50 are formed above the gate electrode 46, the source/drain implant regions 44 and a portion of the extension implant regions 46. That is, the relatively thin metal silicide contacts 50 are formed above the implanted regions between the sidewall spacer 40A and the insulation regions 42. The metal silicide contacts 50 may have a thickness ranging from approximately 40-210 Å. The metal silicide contacts 50 may be formed by depositing an appropriate layer of refractory metal (not shown), e.g., cobalt, titanium, nickel, platinum, tungsten, etc., having a thickness of approximately 20-150 Å, and performing one or more anneal processes to convert the refractory metal in contact with silicon to a metal silicide, e.g, cobalt silicide, titanium silicide, nickel silicide, platinum silicide, tungsten silicide, etc. In one illustrative embodiment, the metal silicide contacts 50 are formed by depositing a layer of cobalt at a thickness ranging from approximately 20-150 Å and converting portions of that refractory metal layer to the metal silicide contacts 50 comprised of cobalt silicide having a thickness ranging from approximately 40-210 Å. Note that, the metal silicide contacts 50 are relatively thin as compared to prior art silicide processing techniques wherein the silicide contacts above only the source/drain regions of a device may have a thickness ranging from approximately 80-300 Å. Moreover, it should be noted that the metal silicide contacts 50 shown in FIG. 2C are positioned closer to the gate electrode 46 due to the relatively thin sidewall spacer 40A. Positioning the metal silicide contacts 50 in this manner reduces the resistance of the path electrons will take when the device is operating, thereby improving device performance.

Thereafter, as shown in FIG. 2D, a second sidewall spacer 52 is formed adjacent the sidewall spacer 40A and above a portion of the metal silicide contact 50. The second sidewall spacer 52 may be formed from a variety of materials, e.g., silicon dioxide or the others referenced above with respect to the sidewall spacer 40. Moreover, the second sidewall spacer 52 may be formed by depositing an appropriate layer of material (not shown) and thereafter performing one or more anisotropic etching processes. In one illustrative embodiment, the second sidewall spacer 52 is comprised of silicon dioxide that has a thickness 53 at its base, e.g., at the point at which intersects the metal silicide contact 50, that ranges from approximately 200-1000 Å.

Thereafter, an additional metal silicide layer or contact 50A may be formed above the previously formed metal silicide contacts 50 to increase the thickness of the previously formed metal silicide contacts 50 above the gate electrode 46 and above the portions of the source/drain regions 49 that extend beyond the second sidewall spacer 52. That is, the metal silicide contacts 50A above the source/drain regions of the device are generally self-aligned with respect to the second sidewall spacer 52. For purposes of clarity, the metal silicide contacts 50 and 50A are shaded differently in the drawings. Such processing may be performed by forming an appropriate layer of refractory metal (not shown), e.g., cobalt, titanium, nickel, platinum, tungsten, etc., and thereafter performing one or more anneal processes to convert portions of the refractory metal layer to a metal silicide.

The metal silicide contacts 50A will typically be thicker than the contacts 50. In one embodiment, the metal silicide contacts 50A may have a thickness ranging from approximately 180-300 Å. In one illustrative embodiment, an additional layer of cobalt having a thickness ranging from approximately 130-160 Å may be formed above the metal silicide contacts 50 and the second sidewall spacer 52 and thereafter converted to a metal silicide, e.g., cobalt silicide. The result of this processing is that the metal silicide contact above the gate electrode 46, as well as the metal silicide contacts above the source/drain regions lying beyond the second sidewall spacer 52 are relatively thick, i.e., on the order of approximately 220-610 Å. That is, in accordance with the inventive method disclosed herein, the source/drain regions are provided with metal silicide contacts 54 having a dual thickness or a stepped thickness profile. For example, the portion of the metal silicide contact positioned underneath the second sidewall spacer 52 adjacent the sidewall spacer 40A may have a thickness ranging from approximately 40-210 Å, whereas the portion of the metal silicide contact above the source/drain region beyond the sidewall spacer 52 may have a thickness ranging from approximately 300-435 Å.

The dual thickness metal silicide contacts 54 provide several advantages. First, a relatively thin metal silicide is formed above the portion of the extension implant region 46 that is not protected by the sidewall spacer 40A, thereby reducing the electrical resistance to electrons flowing through this area and, accordingly, improving device performance. Second, a metal silicide region is positioned closer to the channel region of the device which may also tend to increase device performance. Other advantages may also be recognized by those skilled in the art.

The present invention is directed to a novel transistor device and a method of making same. In one illustrative embodiment, the transistor comprises a semiconducting substrate 30, a gate insulation layer 48 positioned above the substrate 30, a gate electrode 46 positioned above the gate insulation layer 48, and a plurality of source/drain regions formed in the substrate 30. The transistor further comprises a first 40A and a second 52 sidewall spacer positioned adjacent the gate electrode 46, and a metal silicide layer 54 formed above each of the source/drain regions, a portion of the metal silicide layer 54 being positioned adjacent the first sidewall spacer 40A and under the second sidewall spacer 52. Of course, additional sidewall spacers may be present on the device. For example, in the case of a PMOS device, a relatively small spacer (not shown) may be positioned adjacent the gate electrode 46 prior to performing any implant processes. In such a situation, the sidewall spacer 40A is still considered to be formed adjacent the gate electrode 46.

The inventive method described herein comprises forming a gate insulation layer 48 and a gate electrode 46 above a semiconducting substrate 30, forming a first sidewall spacer 40A adjacent the gate electrode 46, forming a metal silicide layer 50 adjacent the first sidewall spacer 40A and above previously formed implant regions in the substrate 30, forming a second sidewall spacer 52 above a portion of the metal silicide layer 50, and forming additional metal silicide material 50A above the metal silicide layer 50 extending beyond the second sidewall spacer 52.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A transistor, comprising:
a semiconducting substrate;
a gate insulation layer positioned above said substrate;
a gate electrode positioned above said gate insulation layer;
a plurality of source/drain regions formed in said substrate;
a first and a second sidewall spacer positioned adjacent said gate electrode; and
a metal silicide layer formed above each of said source/drain regions, a portion of said metal silicide layer being positioned adjacent said first sidewall spacer and under said second sidewall spacer.

2. The transistor of claim 1, wherein said semiconducting substrate is comprised of silicon.

3. The transistor of claim 1, wherein said gate insulation layer is comprised of at least one of a metal oxide, silicon dioxide, silicon nitride, an oxynitride, and a silicon nitride/silicon dioxide bilayer.

4. The transistor of claim 1, wherein said gate electrode is comprised of polysilicon or a metal.

5. The transistor of claim 1, wherein said source/drain regions are comprised of a source/drain implant region and an extension implant region.

6. The transistor of claim 1, wherein said first sidewall spacer is comprised of at least one of an oxide, a nitride, an oxynitride, silicon dioxide, silicon oxynitride and silicon nitride.

7. The transistor of claim 1, wherein said second sidewall spacer is comprised of at least one of an oxide, a nitride, an oxynitride, silicon dioxide, silicon oxynitride and silicon nitride.

8. The transistor of claim 1, wherein said first sidewall spacer has a thickness at its base that ranges from approximately 50-250 Å.

9. The transistor of claim 1, wherein said second sidewall spacer has a thickness at its base that ranges from approximately 200-1000 Å.

10. The transistor of claim 1, wherein said metal silicide layer is comprised of at least one of cobalt silicide, titanium silicide, nickel silicide, platinum silicide and tungsten silicide.

11. The transistor of claim 1, wherein said portion of said metal silicide layer positioned under said second sidewall spacer is thinner than the portion of the metal silicide layer extending beyond said second sidewall spacer.

12. The transistor of claim 1, wherein said portion of said metal silicide layer positioned under said second sidewall spacer has a thickness ranging from approximately 40-210 Å.

13. The transistor of claim 1, wherein the portion of said metal silicide layer extending beyond said second sidewall spacer has a thickness ranging from approximately 220-610 Å.

14. The transistor of claim 1, further comprising a metal silicide layer positioned above said gate electrode.

15. A transistor, comprising:
a semiconducting substrate comprised of silicon;
a gate insulation layer positioned above said substrate;
a gate electrode positioned above said gate insulation layer;
a plurality of source/drain regions formed in said substrate;
a first and a second sidewall spacer positioned adjacent said gate electrode; and
a metal silicide layer formed above each of said source/drain regions, a first portion of said metal silicide layer being positioned adjacent said first sidewall spacer and under said second sidewall spacer, said first portion of said metal silicide layer positioned under said second sidewall spacer being thinner than a second portion of the metal silicide layer extending beyond said second sidewall spacer.

16. The transistor of claim 15, wherein said gate insulation layer is comprised of at least one of a metal oxide, silicon dioxide, silicon nitride, an oxynitride, and a silicon nitride/silicon dioxide bilayer.

17. The transistor of claim 15, wherein said gate electrode is comprised of polysilicon or a metal.

18. The transistor of claim 15, wherein said source/drain regions are comprised of a source/drain implant region and an extension implant region.

19. The transistor of claim 15, wherein said first sidewall spacer is comprised of at least one of an oxide, a nitride, an oxynitride, silicon dioxide, silicon oxynitride and silicon nitride.

20. The transistor of claim 15, wherein said second sidewall spacer is comprised of at least one of an oxide, a nitride, an oxynitride, silicon dioxide, silicon oxynitride and silicon nitride.

21. The transistor of claim 15, wherein said first sidewall spacer has a thickness at its base that ranges from approximately 50-250 Å.

22. The transistor of claim 15, wherein said second sidewall spacer has a thickness at its base that ranges from approximately 200-1000 Å.

23. The transistor of claim 15, wherein said metal silicide layer is comprised of at least one of cobalt silicide, titanium silicide, nickel silicide, platinum silicide and tungsten silicide.

24. The transistor of claim 15, wherein said first portion of said metal silicide layer positioned under said second sidewall spacer has a thickness ranging from approximately 40-210 Å.

25. The transistor of claim 15, wherein said second portion of said metal silicide layer extending beyond said second sidewall spacer has a thickness ranging from approximately 220-610 Å.

26. The transistor of claim 15, further comprising a metal silicide layer positioned above said gate electrode.

27. A transistor, comprising:
a semiconducting substrate;
a gate insulation layer positioned above said substrate;
a gate electrode positioned above said gate insulation layer;
a plurality of source/drain regions formed in said substrate; and
a metal silicide layer formed above each of said source/drain regions, said metal silicide layer having a stepped thickness profile.

28. The transistor of claim 27, wherein said semiconducting substrate is comprised of silicon.

29. The transistor of claim 27, wherein said gate insulation layer is comprised of at least one of a metal oxide, silicon dioxide, silicon nitride, an oxynitride, and a silicon nitride/silicon dioxide bilayer.

30. The transistor of claim 27, wherein said gate electrode is comprised of polysilicon or a metal.

31. The transistor of claim 27, wherein said source/drain regions are comprised of a source/drain implant region and an extension implant region.

32. The transistor of claim 27, wherein said metal silicide within said stepped thickness profile has a first portion and a second portion, said first portion being thinner than said second portion.

33. The transistor of claim 32, further comprising:
a first sidewall spacer positioned between said gate electrode and said first portion of said metal silicide layer; and
a second sidewall spacer positioned adjacent said first sidewall spacer and above said first portion of said metal silicide layer.

34. The transistor of claim 33, wherein said first sidewall spacer is comprised of at least one of an oxide, a nitride, an oxynitride, silicon dioxide, silicon oxynitride and silicon nitride.

35. The transistor of claim 33, wherein said second sidewall spacer is comprised of at least one of an oxide, a nitride, an oxynitride, silicon dioxide, silicon oxynitride and silicon nitride.

36. The transistor of claim 33, wherein said first sidewall spacer has a thickness at its base that ranges from approximately 50-250 Å.

37. The transistor of claim 33, wherein said second sidewall spacer has a thickness at its base that ranges from approximately 200-1000 Å.

38. The transistor of claim 27, wherein said metal silicide layer is comprised of at least one of cobalt silicide, titanium silicide, nickel silicide, platinum silicide and tungsten silicide.

39. The transistor of claim 33, wherein said first portion of said metal silicide layer has a thickness ranging from approximately 40-210 Å.

40. The transistor of claim 33, wherein said second portion of said metal silicide layer has a thickness ranging from approximately 220-610 Å.

41. The transistor of claim 27, further comprising a metal silicide layer positioned above said gate electrode.

42. A method of forming a transistor, comprising:
forming a gate insulation layer and a gate electrode above a semiconducting substrate;
forming a first sidewall spacer adjacent said gate electrode;
forming a metal silicide layer adjacent said first sidewall spacer and above previously formed implant regions in said substrate;
forming a second sidewall spacer above a portion of said metal silicide layer; and
forming additional metal silicide material above said metal silicide layer extending beyond said second sidewall spacer.

43. The method of claim 42, wherein said gate insulation layer is comprised of silicon dioxide and said gate electrode is comprised of polysilicon.

44. The method of claim 42, wherein forming a first sidewall spacer adjacent said gate electrode comprises forming a first sidewall spacer comprised of at least one of a metal oxide, silicon dioxide, silicon nitride, an oxynitride, and a silicon nitride/silicon dioxide bilayer adjacent said gate electrode.

45. The method of claim 42, wherein forming a first sidewall spacer adjacent said gate electrode comprises depositing a layer of material and performing an anisotropic etching process.

46. The method of claim 42, wherein forming a first metal spacer adjacent said gate electrode comprises reducing a thickness of a previously formed sidewall spacer by performing an anisotropic etching process.

47. The method of claim 42, wherein said metal silicide layer is comprised of at least one of cobalt silicide, titanium silicide, nickel silicide, platinum silicide and tungsten silicide.

48. The method of claim 42, wherein forming a metal silicide layer adjacent said first sidewall spacer and above previously formed implant regions in said substrate comprises depositing a layer of refractory metal above said first sidewall spacer and said previously formed implant regions in said substrate and performing at least one anneal process.

49. The method of claim 42, wherein said metal silicide layer has a thickness ranging from approximately 40-210 Å.

50. The method of claim 42, wherein forming a second sidewall spacer above a portion of said metal silicide layer comprises forming a second sidewall spacer comprised of at least one of an oxide, a nitride, an oxynitride, silicon dioxide, silicon oxynitride and silicon nitride above a portion of said metal silicide layer.

51. The method of claim 42, wherein forming a second sidewall spacer above a portion of said metal silicide layer comprises forming a second sidewall spacer having a thickness ranging from approximately 200-1000 Å above a portion of said metal silicide layer.

52. The method of claim 42, wherein forming a second sidewall spacer above a portion of said metal silicide layer comprises depositing a layer of spacer material and performing an anisotropic etching process.

53. The method of claim 42, wherein forming a second sidewall spacer above a portion of said metal silicide layer comprises forming a second sidewall spacer above a portion of said metal silicide layer and adjacent said first sidewall spacer.

54. The method of claim 42, wherein said additional metal silicide material is comprised of at least one of cobalt silicide, titanium silicide, nickel silicide, platinum silicide and tungsten silicide.

55. The method of claim 42, wherein forming additional metal silicide material above said metal silicide layer extending beyond said second sidewall spacer comprises depositing a layer of refractory metal above said second sidewall spacer and above said metal silicide layer extending beyond said second sidewall spacer and performing at least one anneal process.

56. The method of claim 42, wherein forming additional metal silicide material above said metal silicide layer extending beyond said second sidewall spacer comprises forming additional metal silicide material above said metal silicide layer extending beyond said second sidewall spacer to increase a thickness of said metal silicide layer extending beyond said second sidewall spacer to approximately 220-610 Å.

57. A method of forming a transistor, comprising:
forming a gate insulation layer and a gate electrode above a semiconducting substrate;
forming a first sidewall spacer comprised of at least one of an oxide, a nitride, an oxynitride, silicon dioxide, silicon oxynitride and silicon adjacent said gate electrode;
forming a metal silicide layer comprised of at least one of cobalt silicide, titanium silicide, nickel silicide, platinum silicide and tungsten silicide adjacent said first sidewall spacer and above previously formed implant regions in said substrate;
forming a second sidewall spacer comprised of at least one of an oxide, a nitride, an oxynitride, silicon dioxide, silicon oxynitride and silicon nitride above a portion of said metal silicide layer and adjacent said first sidewall spacer; and
forming additional metal silicide material above said metal silicide layer extending beyond said second sidewall spacer.

58. The method of claim 57, wherein said gate insulation layer is comprised of silicon dioxide and said gate electrode is comprised of polysilicon.

59. The method of claim 57, wherein forming a metal silicide layer adjacent said first sidewall spacer and above previously formed implant regions in said substrate comprises depositing a layer of material comprised of at least one of cobalt, titanium, nickel, platinum and tungsten and performing an anisotropic etching process.

60. The method of claim 57, wherein forming a metal silicide layer adjacent said first sidewall spacer and above previously formed implant regions in said substrate comprises reducing a thickness of a previously formed sidewall spacer by performing an anisotropic etching process.

61. The method of claim 57, wherein forming a metal silicide layer adjacent said first sidewall spacer and above previously formed implant regions in said substrate comprises depositing a layer of refractory metal comprised of at least one of cobalt, titanium, nickel, platinum and tungsten above said first sidewall spacer and said previously formed implant regions in said substrate and performing at least one anneal process.

62. The method of claim 57, wherein said metal silicide layer has a thickness ranging from approximately 40-210 Å.

63. The method of claim 57, wherein forming a second sidewall spacer above a portion of said metal silicide layer and adjacent said first sidewall spacer comprises forming a second sidewall spacer having a thickness ranging from approximately 200-1000 Å above a portion of said metal silicide layer and adjacent said first sidewall spacer.

64. The method of claim 57, wherein forming a second sidewall spacer above a portion of said metal silicide layer and adjacent said first sidewall spacer comprises depositing a layer of spacer material and performing an anisotropic etching process.

65. The method of claim 57, wherein forming additional metal silicide material above said metal silicide layer extending beyond said second sidewall spacer comprises depositing a layer of refractory metal above said second sidewall spacer and above said metal silicide layer extending beyond said second sidewall spacer, and performing at least one anneal process.

66. The method of claim 57, wherein forming additional metal silicide material above said metal silicide layer extending beyond said second sidewall spacer comprises forming additional metal silicide material above said metal silicide layer extending beyond said second sidewall spacer to increase a thickness of said metal silicide layer extending beyond said second sidewall spacer to approximately 220-610 Å.
